(19) United States
(12) Patent Application Publication
(10) Pub. No.: US 2018/0052203 A1
(43) Pub. Date: Feb. 22, 2018

(54) METHOD FOR ENABLING CPU-JTAG DEBUGGER CONNECTION OR IMPROVING ITS PERFORMANCE FOR MULTI-CLOCK DESIGNS RUNNING ON FPGA OR EMULATION SYSTEMS

(71) Applicant: PRATEEK SIKKA, New Delhi (IN)

(72) Inventor: PRATEEK SIKKA, New Delhi (IN)

(21) Appl. No.: 15/414,107

(22) Filed: Jan. 24, 2017

(30) Foreign Application Priority Data
Aug. 22, 2016 (IN) 201611028589

(51) Int. Cl. G01R 31/317; G01R 31/3177

(52) U.S. Cl. CPC G01R 31/31725; G01R 31/3177; G01R 31/31705

(57) ABSTRACT

The present invention provides a method to improve the JTAG debugger connection performance (TCK speed) with CPU for multi-clock designs running on Emulation or FPGA systems by creating two separate emulation or FPGA builds i.e. first build with actual frequency plan and second one with flat frequency plan (all clocks running at same frequency). The method is even effective for enabling JTAG connection to CPU in cases of designs where the running frequency of CPU is so low (due to complex clocking structure like uneven clock frequency ratios and critical paths of the design) that JTAG connection is not possible at all.

### FIELD OF INVENTION

The present invention relates to a method for enabling a JTAG debugger connection to a CPU of a multi-clock design running on low frequency on Emulation or FPGA systems for cases where the connection is not possible due to speed limitations. The method of invention also improves the JTAG connection performance (TCK speed) in the case where speed of connection between CPU and external JTAG debugger is slow.

### PRIOR ART AND PROBLEM TO BE SOLVED

In this electronics era, the market growing rapidly with increase in launch of new and improved products having high end technology. With every improvement, the IC design complexity is increasing and therefore testing of product is all the more required.

JTAG (Joint test action group) is an electronics industry association formed in 1985 for developing a method of verifying designs and testing PCBs/VLSI chips after manufacture.

JTAG provides a high degree of testability for building high technology electronic products. JTAG eliminates the need for a large number of test vectors and facilitates shorter test times, higher test coverage, increased diagnostic capability with lower capital equipment cost.

Further, due to increase in design size and complexity of clock trees in VLSI designs, the critical paths grow longer and hence complexity of placement and routing also increases. This also causes the maximum compile frequency (F-max as reported by synthesis tools) to reduce.

Therefore, for complex designs with multiple clocks especially with uneven clock distribution on FPGA and emulation systems, the synthesis frequency is low. This causes the CPU clock in the design to run at a very low “real world frequency” on FPGA or Emulation system. To add to the problem, most commercially available JTAG debuggers require TCK to run at a frequency which is an order of magnitude slower than the CPU clock in order to ensure a valid communication link. Hence, JTAG connection to external world is not possible in most cases for such designs which hampers the debug visibility inside the chip at a pre-silicon stage during emulation.

So, the only option to enable pre-silicon JTAG debug in such cases is to use a simulation tool and use IP models for JTAG devices. However, this approach of going away from Emulation and hardware prototyping has its own limitations of speed and accuracy.

In case, even if the connection to external JTAG peripheral is successful on a hardware platform for a design with complex clock tree and critical paths, the performance is too slow and hence operations like code download into memory could take lots of time causing an adverse effect on the overall debug time and hence verification time, thereby increasing time to market of the product.

With increase in turnaround time and the fact that VLSI fabrication is an expensive process, debugging performed at pre-silicon stage is even more important. Detection of bugs at post-silicon stage means the design needs to be fixed and again fabricated thereby causing loss of invested money and time.

The prior-arts described below are directed towards improving the connection performance for complex designs. U.S. Pat. No. 6,983,441 discloses a system and method for embedding a Joint Test Action Group (JTAG) host controller into a field programmable gate array (FPGA) for platform development and DSP programming, and boundary scan of targeted hardware using JTAG commands and architecture is described. In the said invention functionality of a JTAG emulator pod and controller card is emulated inside of an FPGA. The memory array is bussed directly into the FPGA core, thereby bypassing the traditional PC card host controller. However, if a JTAG device like Lauterbach Trace32 needs to be connected to load an OS like Linux into the memory of a system with an ARM CPU, it may not work well. Moreover, if the methodology of bypassing the traditional PC card host controller altogether is used, there are chances of missing uncovered bugs in JTAG signal connectivity from the chip top to the CPU which may lead to more problems at post-silicon phase.

Further, CN 101140315 discloses FPGA logical code downloading method under JTAG downloading mode and downloading system thereof in order to reduce time on FPGA logic code download and improve FPGA debugging efficiency. The invention helps to download the code into multiple designs running on different FPGAs. However, it does not help to improve the JTAG performance of a single complex clock tree design running on a hardware platform like FPGA. Also, in the cases where a single SoC design with complex clock trees is running on the FPGA and JTAG is unable to connect due to low CPU frequency, this invention may not be able to help.

Therefore, there is a need for a solution to overcome the aforesaid difficulties. The present invention solves the aforesaid problems by providing a method to improve the JTAG connection performance (TCK speed) for designs where the CPU real world running speed is slow, which is typically the case for most complex, multi-clock designs running on emulation or FPGA systems. The same invention also helps to achieve a valid connection between CPU and JTAG in cases where the frequency is too low that connection is not at all possible to establish.

### SUMMARY OF THE INVENTION

The primary object of the present invention is to provide a method to improve connection performance of JTAG for complex multi-clock designs on emulation as well as FPGA systems by creating two separate builds for the design: one with actual clock frequency and another with flat frequency i.e. a build wherein all clock frequencies of the design are specified as same.

Another object of the present invention is to use the flat frequency plan during verification test while loading code in the memory through JTAG and use the actual frequency plan during rest of the verification process.

Yet another object of the invention is to switch to any of the two frequency plans depending upon the need to connect to JTAG during verification test flow.

Other objects and advantages of the present invention will become apparent from the following description taken in connection with the accompanying drawings, wherein, by way of illustration and example, the aspects of the present invention are disclosed.

### BRIEF DESCRIPTION OF THE DRAWINGS

The present invention will be better understood after reading the following detailed description of the presently preferred aspects thereof with reference to the appended drawings, in which:

FIG. 1 illustrates the flow chart delineating the method of working of present invention;

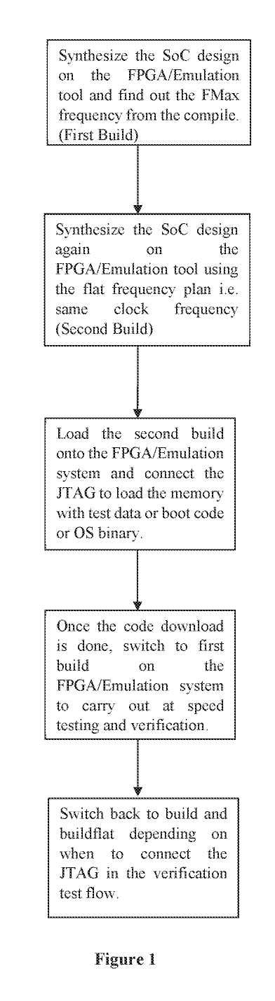

FIG. 2 illustrates the block diagram of the design with an embedded CPU connected with an external JTAG debugger.

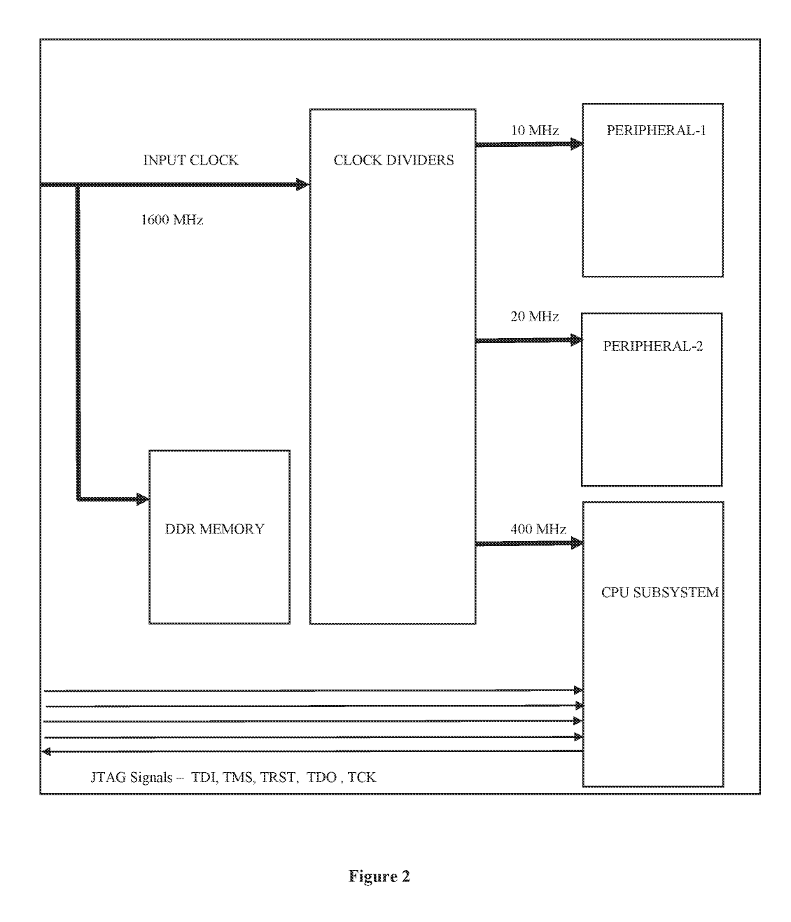

### DETAILED DESCRIPTION OF THE INVENTION

The following description describes various features and functions of the disclosed method with reference to the accompanying figures. In the figures, similar symbols identify similar components, unless context dictates otherwise. The illustrative aspects described herein are not meant to be limiting. It may be readily understood that certain aspects of the disclosed method can be arranged and combined in a wide variety of different configurations, all of which are contemplated herein.

A design with complex clock trees when synthesized onto an FPGA hardware or Emulator, the maximum frequency of operation (F-max) is typically low due to the fact that the compiler toolchain has to handle complex timing paths. Further, since for most commercial JTAG debuggers, TCK frequency is required to be an order of magnitude slower than the CPU clock frequency, hence this puts a maximum limit to the speed at which TCK can run. Hence during pre-silicon stage, establishing connection with an external JTAG debugger is a challenge for such designs. Therefore, debugging complex designs during pre-silicon stage is difficult (slow) or not possible at all through an external JTAG debugger

The present invention describes a method that enables external JTAG debugger to be connected to the CPU when CPU clock running frequency is extremely low for the CPU to be connected to JTAG and also improve the JTAG connection performance (TCK speed) in case the connection is slow.

The main aspect of the present invention is a method that enables connection between JTAG and low frequency CPU where connection is not possible. In the method, the connection between JTAG and low frequency CPU is established by creating two separate emulation or FPGA builds. In the method, the SoC design is first synthesized on FPGA or Emulation system using the actual clock frequency plan to obtain F-max (build 1) from the compiler. Now, the SoC design is again synthesized on FPGA or Emulation system using a flat frequency plan to obtain F-max2 (build 2) i.e. all clock frequencies of the design are specified as same in this build. Whenever JTAG is required to be connected (e.g. downloading the code) during the verification test process, flat frequency (build 2) is loaded onto the Emulation or FPGA system. Otherwise actual frequency (build 1) is used for rest of the verification process.

Another aspect of the present invention is a method to improve JTAG connection performance with CPU where the connection speed is slow. In the method, the connection performance between JTAG and CPU is improved by creating two separate emulation or FPGA builds. In the method, the SoC design is first synthesized on FPGA or Emulation system using the actual clock frequency plan to obtain F-max (build 1) from the compiler. Now, the SoC design is again synthesized on FPGA or Emulation system using a flat frequency plan to obtain F-max2 (build 2) i.e. all clock frequencies of the design are specified as same. Whenever JTAG is required to be connected (e.g. downloading the code) during the verification process, flat frequency (build 2) is loaded onto the Emulation or FPGA system. Otherwise compilation frequency (build 1) is used for rest of the verification process. In this way, the connection performance (TCK speed) is improved.

In the present invention, during functional run of the test, binary file corresponding to actual frequency plan is loaded and whenever JTAG is required to be connected, the binary file corresponding to the flat frequency plan is downloaded to connect JTAG at a higher speed (TCK). Therefore, during the initial phase of the verification test when the code is loaded in the memory through JTAG, flat frequency (build 2) is used and then switched to actual frequency plan (build 1) later in the test by changing the downloaded synthesis output file/binary.

In the flat frequency build (build 2), same clock frequencies are supplied as constraints to synthesis tool.

For any event based FPGA or emulation compiler toolchain, all the design clocks are derived from a fastest clock with help of dividers. In one instance, if a design has 3 clocks say 100 MHz, 50 MHz and 10 MHz, .after placement and routing, if the F-max is 2 kHz then the design clocks run at 2 kHz, 1 kHz and 200 Hz respectively in the same ratios as the original frequency ratios.

Now if the design runs for 200 cycles of the slowest clock, then entire test case takes 1 second of wall clock time to complete on the emulation platform (1/200 s *200). However, if all the clocks in a design are having the same frequency, then the entire test case takes 0.1 second (wall clock time) to run completely.

In another instance, a design having 4 clocks running at 2000 MHz (DDR memory clock), 1000 MHz (another memory clock), 500 MHz (CPU clock) and 10 MHz (a peripheral clock). Assume that the actual frequency synthesis resulted in F-max of 2 kHz, so the CPU clock runs at 500 Hz in real world. If this design is to be connected to JTAG, then the max frequency at which TCK can run is 50 Hz (assuming a min ratio of 1/10 to CPU clock based on CPU-JTAG architectural limitation). The maximum frequency at which TCK runs is even reduced if the clock frequencies are not even multiples of each other and therefore it practically becomes impossible to connect JTAG with CPU in some of these cases. However, if flat frequency build (build 2) is running, TCK can safely run up to 200 Hz (1/10 * 2kHz) which may be good enough speed for downloading a complete OS image like Linux in few minutes. This is because whenever we communicate to CPU/DUT through JTAG, we do that at a faster rate than the original build.

In addition to above, the total run time of the test is improved using flat frequency build plan, lowering the overall Emulation/FPGA usage time which in turn lowers the process cost and time to market of the product.

The design is fully digital and synthesizable as only the frequencies of operation are changing which are the inputs to the synthesis tool or build. The design with any number of different clocks irrespective of the frequency relation between them, can be verified using JTAG with improved connection performance (TCK) as long as FPGA/emulation platform being used supports connection to external hardware JTAG debuggers. The method of present invention works for all JTAG hardware which connect to industry standard FPGAs and Emulation systems. By simply enabling a switch to change the downloaded design binary on the emulator or FPGA system, one can achieve better JTAG performance and hence easier debug along with faster runtime.

The compile speed (F-max) and run time speed are better optimized using the method of flat frequency plans irrespective of the target emulation engine/compile platform. The methodology applies to all JTAG debug devices which connect to emulation or FPGA boards of different kinds. Since the time to run the test is reduced, the regression time and hence verification time is also cut down which in turn helps to reduce time to market for electronic VLSI designs. Also, since the run time is reduced, it helps in optimal usage of emulator up time and hence hardware resources are used in a much optimal manner as large number of designs or test cases can be run in a shorter duration.

While the present invention has been described with reference to one or more preferred aspects, which aspects have been set forth in considerable detail for the purposes of making a complete disclosure of the invention, such aspects are merely exemplary and are not intended to be limiting or represent an exhaustive enumeration of all aspects of the invention. The scope of the invention, therefore, shall be defined solely by the following claims. Further, it will be apparent to those of skill in the art that numerous changes may be made in such details without departing from the spirit and the principles of the invention.

1. A method for enabling CPU-JTAG debugger connection on an emulation or FPGA systems, wherein the method comprising:
creating two separate builds for the design by synthesizing SoC design on FPGA or Emulation system to obtain compile or synthesis frequency (F-maxl) as first build;
repeating synthesis of SoC design on FPGA or Emulation system with flat frequency plan as second build (F-max2);
running the system with first build during most of verification(test) process; and
switching to second build when connection with JTAG debugger is required during the verification process.

2. A method for improving CPU-JTAG debugger connection performance for multi-clock designs running on FPGA or Emulation systems, wherein the method comprising:
creating two separate builds for the design by synthesizing SoC design on FPGA or Emulation system to obtain compile or synthesis frequency (F-max1) as first build;
repeating synthesis of SoC design on FPGA or Emulation system with flat frequency as second build (F-max2);
running the system with first build during most of verification(test) process; and
switching to second build when connection with debugger is required during the verification process.

3. The method as claimed in claim 1, wherein during single test run, the FPGA or Emulation system build (synthesized binary) is switched multiple times between first build and second build as per the verification or test requirements.

4. The method as claimed in claim 1, wherein first build is actual clock frequency and second build is flat frequency i.e. all clock frequencies of the design (supplied as constraints to synthesis tool) are same.

5. The method as claimed in claim 1, wherein during initial phase of the verification test second build is used to load the code in memory through debugger and is switched to a first build by changing downloaded synthesis output or binary/bit file.

6. The method as claimed in claim 1, wherein different slower design clocks are derived from fastest clock of the design by means of divider circuitry by any event based compiler toolchain for the FPGA or Emulation.

7. The method as claimed in claim 2, wherein during single test run, the FPGA or Emulation system build (synthesized binary) is switched multiple times between first build and second build as per the verification or test requirements.

8. The method as claimed in claim 2, wherein first build is actual clock frequency and second build is flat frequency i.e. all clock frequencies of the design (supplied as constraints to synthesis tool) are same.

9. The method as claimed in claim 2, wherein during initial phase of the verification test second build is used to load the code in memory through debugger and is switched to a first build by changing downloaded synthesis output or binary/bit file.
